(19) United States
(12) Patent Application Publication
(10) Pub. No.: US 2014/0008652 A1
(43) Pub. Date: Jan. 9, 2014

(54) THROUGH-SUBSTRATE VIA STRUCTURE

(71) Applicants: Tzu-Chien Hsu, Hsinchu County (TW); Tzu-Kun Ku, Hsinchu City (TW); Cha-Hsin Lin, Miaoli County (TW)

(72) Inventors: Tzu-Chien Hsu, Hsinchu County (TW); Tzu-Kun Ku, Hsinchu City (TW); Cha-Hsin Lin, Miaoli County (TW)

(73) Assignee: INDUSTRIAL TECHNOLOGY RESEARCH INSTITUTE, Hsinchu (TW)

(21) Appl. No.: 13/589,196

(22) Filed: Aug. 20, 2012

(30) Foreign Application Priority Data
Jul. 3, 2012 (TW) 101123906

(51) Int. Cl. H01L 23/48; H01L 29/16

(52) U.S. Cl. 257/52; 257/774; 257/49; 257/751; 257/E23.011; 257/E29.083

(57) ABSTRACT

A through-substrate via structure including a substrate, a conductive layer, and a parasitic capacitance modulation layer is provided. The substrate has at least one opening. The opening is filled with the conductive layer. The parasitic capacitance modulation layer is disposed between the conductive layer and the substrate. The parasitic capacitance modulation layer is placed around the through-substrate via to reduce the depletion capacitance and further reduce the parasitic capacitance of the through-substrate via. Therefore, during transmission of signals with high frequency, the parasitic capacitance around the through-substrate via is rather small and thereby the operation speed of devices is increased.

### CROSS-REFERENCE TO RELATED APPLICATION

This application claims the priority benefit of Taiwan application serial no. 101123906, filed on Jul. 3, 2012. The entirety of the above-mentioned patent application is hereby incorporated by reference herein and made a part of this specification.

### TECHNICAL FIELD

The technical field relates to a through-substrate via structure.

### BACKGROUND

With the increasing demands for miniaturization of electronic products and high operating speed, three-dimensional (3D) stacked large-scale integration (LSI) circuits have been extensively applied in various electronic devices little by little. The 3D stacked LSI circuits may include stacked packages, stacked dies, and stacked wafers.

In the stacked wafers, a through-silicon via (TSV) technology has been applied to form conductive vias that may extend through a substrate. One TSV-containing substrate may be further stacked onto another TSV-containing substrate to achieve the 3D integration. In particular, the TSVs in different substrates allow signals to be transmitted from one substrate to another substrate without employing conductive wires or using other media. However, during transmission of signals with high frequency, the parasitic capacitance around each TSV may pose a negative impact on the performance of transmission, and thereby the operation speed of devices may be decreased.

### SUMMARY

One of exemplary embodiments comprises a through-substrate via structure that includes a substrate, a conductive layer, and a parasitic capacitance modulation layer is provided. The substrate has at least one opening. The conductive layer fills up the opening. The parasitic capacitance modulation layer is disposed between the conductive layer and the substrate. The parasitic capacitance modulation layer is for reducing a parasitic capacitance around a through-substrate via.

Several exemplary embodiments accompanied with figures are described in detail below to further explain the disclosure.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A and FIG. 1B are schematic cross-sectional views illustrating formation of a through-substrate via structure according to a first embodiment of the disclosure.

FIG. 2A and FIG. 2B are schematic cross-sectional views illustrating formation of a through-substrate via structure according to a second embodiment of the disclosure.

FIG. 3A and FIG. 3B are schematic cross-sectional views illustrating formation of a through-substrate via structure according to a third embodiment of the disclosure.

FIG. 3B-1 is a schematic cross-sectional view illustrating the through-substrate via structure according to the third embodiment of the disclosure.

FIG. 4 shows curves representing relations of the parasitic capacitance to the liner layer thickness in a conventional through-silicon via (TSV) structure, wherein different curves denote cylindrical TSVs with different sizes.

FIG. 5 shows curves representing relations of the parasitic capacitance to the liner layer thickness in a TSV structure described in the disclosure, wherein different curves denote cylindrical TSVs with different sizes.

### DETAILED DESCRIPTION OF DISCLOSED EXEMPLARY EMBODIMENTS

The through-substrate via structure described in the disclosure includes a substrate having at least one opening, a conductive layer filling up the at least one opening, and a parasitic capacitance modulation layer disposed between the conductive layer and the substrate. Wherein, the parasitic capacitance modulation layer serves to reduce the parasitic capacitance around the through-substrate via. Embodiments exemplified below to elaborate the disclosure, which should however not be construed as limitations to the disclosure.

### First Embodiment

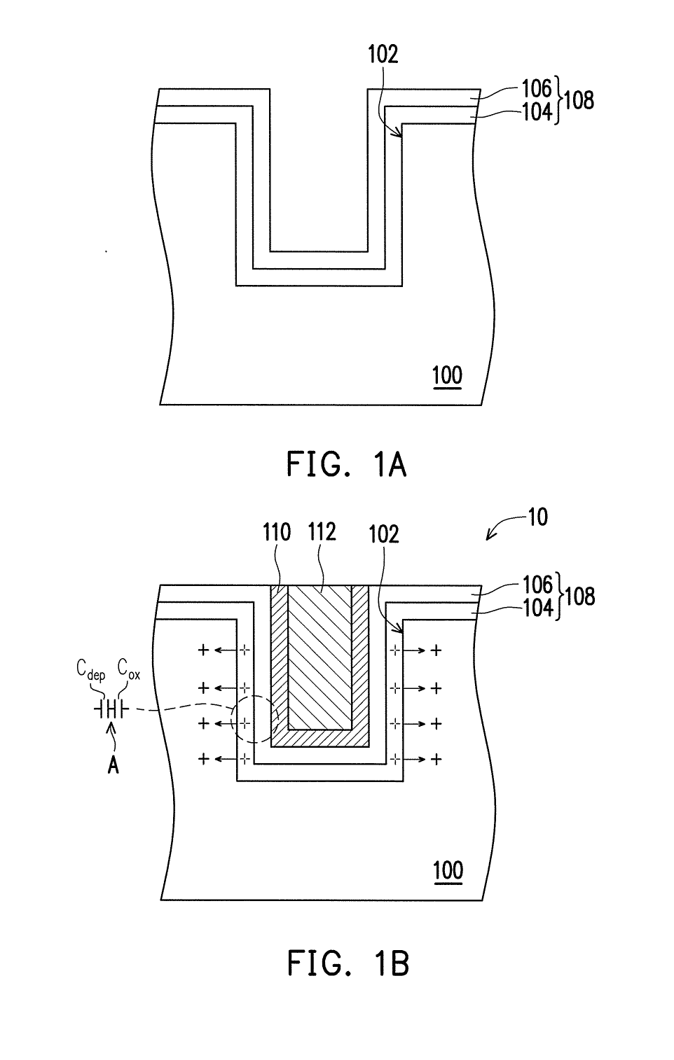

FIG. 1A and FIG. 1B are schematic cross-sectional views illustrating formation of a through-substrate via structure according to a first embodiment of the disclosure.

With reference to FIG. 1A, a substrate 100 is provided. The substrate 100 is, for instance, a silicon substrate. The substrate 100 has at least one opening 102. A method of forming the opening 102 includes forming a patterned mask layer (not shown) on the substrate 100, and then removing a portion of the substrate 100 by using the patterned mask layer as a mask.

A semiconductor layer 104 is conformably formed at least on a surface of the opening 102. A material of the semiconductor layer 104 is, for instance, epitaxial silicon, polysilicon, or amorphous silicon. A method of forming the semiconductor layer 104 includes performing an epitaxial growth process, a chemical vapor deposition (CVD) process, a plasma-enhanced chemical vapor deposition (PECVD) process, or an atomic layer deposition (ALD) process. The conductivity type of the semiconductor layer 104 is the same as that of the substrate 100, and the dopant concentration of the semiconductor layer 104 is lower than the dopant concentration of the substrate 100. For instance, the substrate 100 is a p-type heavily doped (p⁺) silicon substrate, the semiconductor layer 104 is a p-type lightly doped (p⁻) silicon layer, and the dopant concentration of the semiconductor layer 104 is lower than the dopant concentration of the substrate 100 by at least an order of magnitude of 10^{X} to 10⁶, and X is greater than 0. In an embodiment of the disclosure, the dopant of the substrate 100 and the semiconductor layer 104 includes boron, for instance; the dopant concentration of the substrate 100 ranges from about 10¹³ cm⁻³ to about 10²⁰ cm⁻³, for instance; the dopant concentration of the semiconductor layer 104 ranges from about 10⁷ cm⁻³ to about 9.9999×10¹² cm⁻³, for instance. A liner layer 106 is then conformably formed on the semiconductor layer 104. A material of the liner layer 106 may be silicon oxide, silicon nitride, or silicon oxynitride, for instance. A method of forming the liner layer 106 includes performing a CVD process, a PECVD process, or an ALD process. The semiconductor layer 104 and the liner layer 106 together constitute the parasitic capacitance modulation layer 108 described in the first embodiment, and the parasitic capacitance modulation layer 108 serves to reduce the parasitic capacitance around the through-substrate via (e.g., TSV).

With reference to FIG. 1B, the opening 102 is filled with a conductive layer 112. A material of the conductive layer 112 may be copper, tungsten, or polysilicon, for instance. A method of forming the conductive layer 112 includes performing an electroplating process, a CVD process, a PECVD process, or an ALD process. In an embodiment of the disclosure, a barrier layer 110 may be formed between the conductive layer 112 and the parasitic capacitance modulation layer 108 in order to avoid metal diffusion (e.g., copper diffusion). A material of the barrier layer 110 may be titanium nitride, tantalum, or tantalum nitride, for instance. A method of forming the barrier layer 110 includes performing an electroplating process, a CVD process, a PECVD process, or an ALD process. The through-substrate via structure 10 described in the first embodiment is thus completed.

The through-substrate via structure will be further described hereinafter with reference to FIG. 1B. With reference to FIG. 1B, a through-substrate via structure 10 includes a substrate 100, a conductive layer 112, and a parasitic capacitance modulation layer 108. The substrate 100 has at least one opening 102. The conductive layer 112 fills up the opening 102. The parasitic capacitance modulation layer 108 is disposed between the conductive layer 112 and the substrate 100 and applied for reducing the parasitic capacitance around the through-substrate via. Besides, the parasitic capacitance modulation layer 108 includes a liner layer 106 and a semiconductor layer 104. The liner layer 106 is disposed between the conductive layer 112 and the substrate 100. The semiconductor layer 104 is disposed between the liner layer 106 and the substrate 100, and the dopant concentration of the semiconductor layer 104 is lower than the dopant concentration of the substrate 100. In addition, the through-substrate via structure 10 further includes a barrier layer 110 disposed between the conductive layer 112 and the parasitic capacitance modulation layer 108.

The operating principle of the through-substrate via structure is explained hereinafter with reference to FIG. 1B. The circuit A shown in FIG. 1B is the equivalent circuit of the semiconductor layer 104 and the liner layer 106. In the through-substrate via structure described in an embodiment of the disclosure, the capacitance Cₒₓ of the liner layer 106 is serially connected to the depletion capacitance C_{dep}. Since the equivalent capacitance of two serially-connected capacitances is dominated by the smaller capacitance, the reduction of the depletion capacitance C_{dep} can lead to great reduction of the parasitic capacitance C_{TSV} of the through-substrate via. The parasitic capacitance C_{TSV} of the through-substrate via may be represented by the following equation (1). For instance, the equivalent capacitance obtained by serially connecting 1 nF and 10 nF is 0.9 nF (=(1×10)/(1+10)). Therefore, the effective reduction of the depletion capacitance C_{dep} can lead to significant reduction of the overall parasitic capacitance C_{TSV}.

C_{TSV}=Cₒₓ×C_{dep}/(Cₒₓ+C_{dep}) (1)

In the through-substrate via structure 10 described in the first embodiment, the semiconductor layer 104 of the parasitic capacitance modulation layer 108 is applied for reducing the depletion capacitance C_{dep}. The conventional through-substrate via structure is provided without the semiconductor layer 104, and therefore the parasitic capacitance C_{TSV} of the conventional through-substrate via structure is equal to the capacitance Cₒₓ of the liner layer. However, the P⁻ semiconductor layer 104 of the disclosure is arranged to push positive charges in the P⁺ substrate 100 around the liner layer 106 in an outward direction (schematically shown by arrows in FIG. 1B), so as to effectively reduce the depletion capacitance C_{dep} and further significantly reduce the overall parasitic capacitance C_{TSV}.

### Second Embodiment

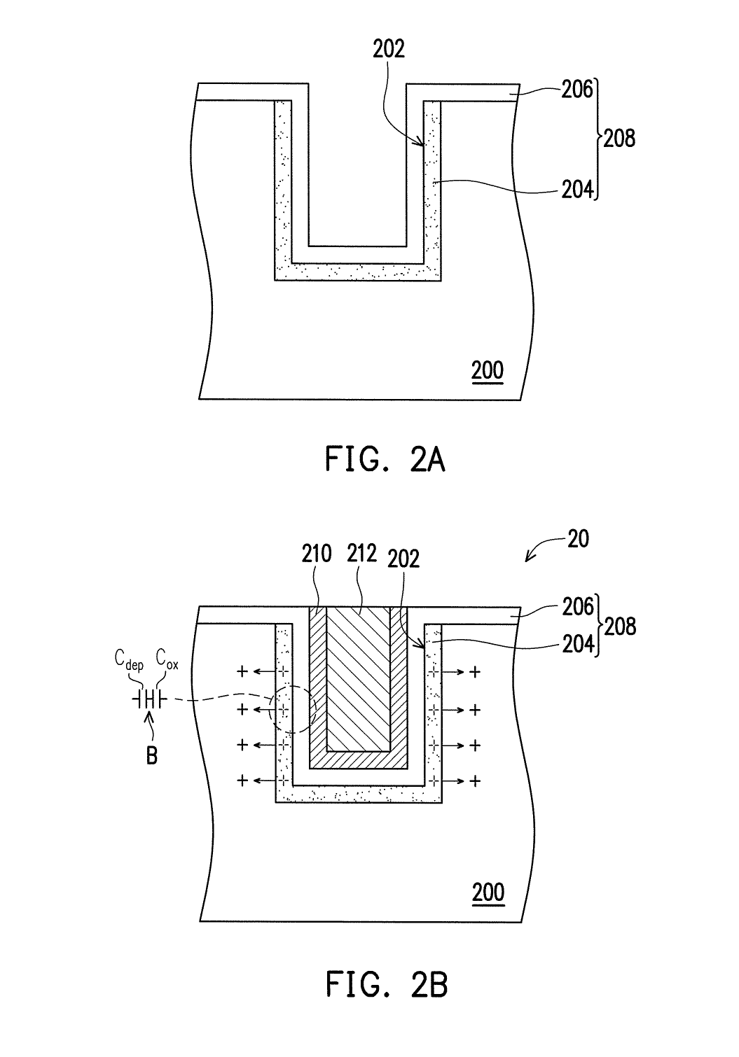

FIG. 2A and FIG. 2B are schematic cross-sectional views illustrating formation of a through-substrate via structure according to a second embodiment of the disclosure.

With reference to FIG. 2A, a substrate 200 is provided. The substrate 200 is, for instance, a silicon substrate. The substrate 200 has at least one opening 202. An ion implantation process is performed on the substrate 200, so as to form a doped region 204 in the substrate 200 around the opening 202. The conductivity type of the doped region 204 is the same as that of the substrate 200, and the dopant concentration of the doped region 204 is lower than the dopant concentration of the substrate 200. Namely, the dopant employed in the ion implantation process and the dopant of the substrate 200 may have opposite conductivity types, and therefore the dopant concentration of the doped region 204 is lower than the dopant concentration of the substrate 200 through counter-doping. In an embodiment of the disclosure, the dopant of the substrate 200 includes boron, and the dopant employed in the ion implantation process includes phosphorous, for instance. Besides, the dopant of the substrate 200 ranges from 10¹³ to 10²⁰, and the dopant of the doped region 204 ranges from 10⁷ to 10¹⁶, for instance. The dopant concentration of the doped region 204 is lower than that of the substrate 200 by at least an order of magnitude of 10^{X} to 10⁶, and X is greater than 0, for instance.

A liner layer 206 is conformably formed at least on a surface of the opening 202. A material of the liner layer 206 may be silicon oxide, silicon nitride, or silicon oxynitride, for instance. A method of forming the liner layer 206 includes performing a CVD process, a PECVD process, or an ALD process. The doped region 204 and the liner layer 206 together constitute the parasitic capacitance modulation layer 208 described in the second embodiment, and the parasitic capacitance modulation layer 208 serves to reduce the parasitic capacitance around the through-silicon via (e.g., TSV).

With reference to FIG. 2B, a conductive layer 212 fills up the opening 202. A material of the conductive layer 212 may be copper, tungsten, or polysilicon, for instance. A method of forming the conductive layer 212 includes performing an electroplating process, a CVD process, a PECVD process, or an ALD process. In an embodiment of the disclosure, a barrier layer 210 may be formed between the conductive layer 212 and the parasitic capacitance modulation layer 208 in order to avoid metal diffusion (e.g., copper diffusion). A material of the barrier layer 210 may be titanium nitride, tantalum, or tantalum nitride, for instance. A method of forming the barrier layer 210 includes performing an electroplating process, a CVD process, a PECVD process, or an ALD process. The through-substrate via structure 20 described in the second embodiment is thus completed.

The through-substrate via structure will be further described hereinafter with reference to FIG. 2B. With reference to FIG. 2B, a through-substrate via structure 20 includes a substrate 200, a conductive layer 212, and a parasitic capacitance modulation layer 208. The substrate 200 has at least one opening 202. The conductive layer 212 fills up the opening 202. The parasitic capacitance modulation layer 208 is disposed between the conductive layer 212 and the substrate 200 and applied for reducing the parasitic capacitance around the through-substrate via. Besides, the parasitic capacitance modulation layer 208 includes a liner layer 206 and a doped region 204. The liner layer 206 is disposed between the conductive layer 212 and the substrate 200. The doped region 204 is disposed between the liner layer 206 and the substrate 200, and the dopant concentration of the doped region 204 is lower than the dopant concentration of the substrate 200. In addition, the through-substrate via structure 20 further includes a barrier layer 210 disposed between the conductive layer 212 and the parasitic capacitance modulation layer 208.

The circuit B shown in FIG. 2B is the equivalent circuit of the doped region 204 and the liner layer 206. In the through-substrate via structure described in an embodiment of the disclosure, the capacitance Cₒₓ of the liner layer 206 is serially connected to the depletion capacitance C_{dep}. Since the equivalent capacitance of two serially-connected capacitances is dominated by the smaller capacitance, the reduction of the depletion capacitance C_{dep} can lead to great reduction of the parasitic capacitance C_{TSV} of the through-substrate via. In the through-substrate via structure 20 described in the second embodiment, the doped region 204 of the parasitic capacitance modulation layer 208 is applied for reducing the depletion capacitance C_{dep}. In the disclosure, the P⁻ doped region 204 is arranged to push positive charges in the P⁺ substrate 200 around the liner layer 206 in an outward direction (schematically shown by arrows in FIG. 2B), so as to effectively reduce the depletion capacitance C_{dep} and further significantly reduce the overall parasitic capacitance C_{TSV}.

### Third Embodiment

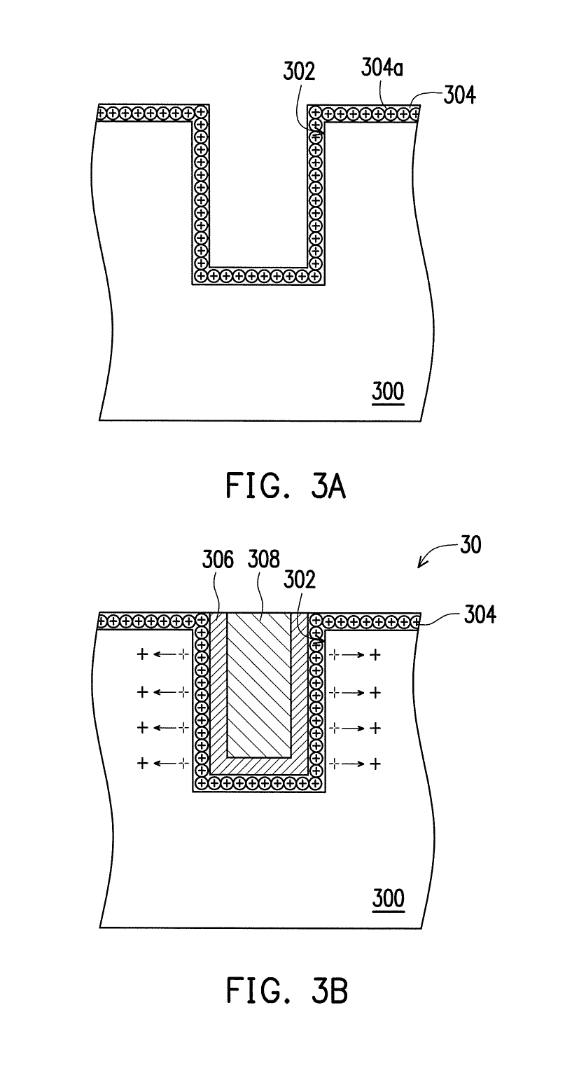

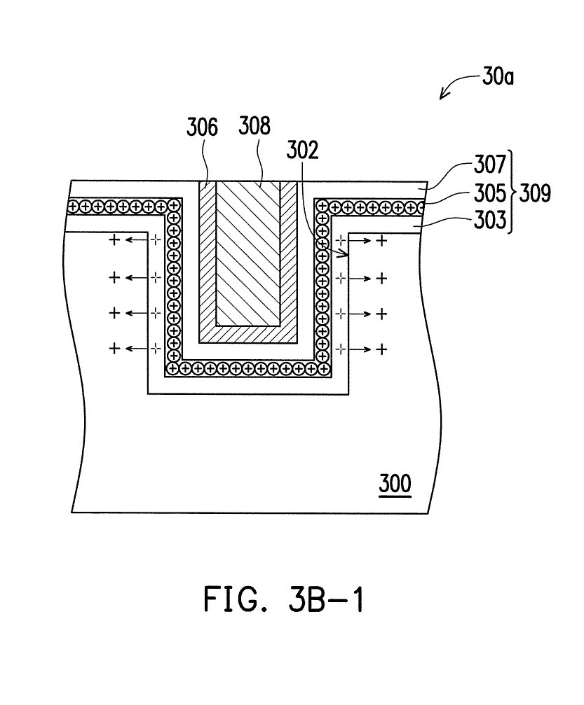

FIG. 3A and FIG. 3B are schematic cross-sectional views illustrating formation of a through-substrate via structure according to a third embodiment of the disclosure.

With reference to FIG. 3A, a substrate 300 is provided. The substrate 300 is, for instance, a silicon substrate. The substrate 300 has at least one opening 302. The parasitic capacitance modulation layer 304 is conformably formed at least on a surface of the opening 302, and the parasitic capacitance modulation layer 304 serves to reduce the parasitic capacitance around the through-silicon via (e.g., TSV). According to the present embodiment, the parasitic capacitance modulation layer 304 is a charged liner layer. When the substrate 300 is a p-type substrate, the charged liner layer has fixed positive charges 304a therein, as shown in FIG. 3A. In another embodiment of the disclosure (not shown), when the substrate 300 is an n-type substrate, the charged liner layer has fixed negative charges therein. A material of the charged liner layer may be silicon oxide, silicon nitride, or silicon oxynitride. A method of forming the charged liner layer includes performing a PECVD process, in which negative charges or positive charges are evenly fixed into the liner layer during the process of forming the liner layer.

With reference to FIG. 3B, a conductive layer 308 fills up the opening 302. A material of the conductive layer 308 may be copper, tungsten, or polysilicon, for instance. A method of forming the conductive layer 308 includes performing an electroplating process, a CVD process, a PECVD process, or an ALD process. In an embodiment of the disclosure, a barrier layer 306 may be formed between the conductive layer 308 and the charged liner layer 304 in order to avoid metal diffusion (e.g., copper diffusion). A material of the barrier layer 306 may be titanium nitride, tantalum, or tantalum nitride, for instance. A method of forming the barrier layer 306 includes performing an electroplating process, a CVD process, a PECVD process, or an ALD process. The through-substrate via structure 30 described in the third embodiment is thus completed.

According to the embodiment, the parasitic capacitance modulation layer is a single charged liner layer, for instance, which should however not be construed as a limitation to the disclosure. In another embodiment, the parasitic capacitance modulation layer may have a multi-layer structure, and the resultant through-substrate via structure 30a is exemplarily shown in FIG. 3B-1. With reference to FIG. 3B-1, the parasitic capacitance modulation layer 309 has a sandwich-like structure including a first dielectric layer 303, a charged liner layer 305, and a second dielectric layer 307. The charged liner layer 305 is disposed between the first dielectric layer 303 and the second dielectric layer 307. In the present embodiment, when the substrate 300 is a p-type substrate, the charged liner layer 305 has fixed positive charges therein, and the first and second dielectric layers 303 and 307 may further prevent the fixed charges in the charged liner layer 305 from escaping from the charged liner layer 305. The first dielectric layer 303 and the second dielectric layer 307 are both non-charged dielectric layers. A material of each of the first dielectric layer 303 and the second dielectric layer 307 includes silicon oxide, silicon nitride, or silicon oxynitride. A method of forming the first and second dielectric layers 303 and 307 includes performing a CVD process, a PECVD process, or an ALD process. In addition, the material of the first dielectric layer 303 can be the same as or different from the material of the second dielectric layer 307.

The through-substrate via structure will be further described hereinafter with reference to FIG. 3B and FIG. 3B-1. With reference to FIG. 3B, a through-substrate via structure 30 includes a substrate 300, a conductive layer 308, and a parasitic capacitance modulation layer 304. The substrate 300 has at least one opening 302. The conductive layer 308 fills up the opening 302. The parasitic capacitance modulation layer 304 is disposed between the conductive layer 308 and the substrate 300 and applied for reducing the parasitic capacitance around the through-substrate via. According to the present embodiment, the parasitic capacitance modulation layer 304 is a charged liner layer. In addition, the through-substrate via structure 30 further includes a barrier layer 306 disposed between the conductive layer 308 and the parasitic capacitance modulation layer 304.

With reference to FIG. 3B-1, a through-substrate via structure 30a includes a substrate 300, a conductive layer 308, and a parasitic capacitance modulation layer 309. The substrate 300 has at least one opening 302. The conductive layer 308 fills up the opening 302. The parasitic capacitance modulation layer 309 is disposed between the conductive layer 308 and the substrate 300 and applied for reducing the parasitic capacitance around the through-substrate via. The parasitic capacitance modulation layer 309 includes a first dielectric layer 303, a charged liner layer 305, and a second dielectric layer 307. The charged liner layer 305 is disposed between the conductive layer 308 and the substrate 300. The first dielectric layer 303 is disposed between the charge liner layer 305 and the substrate 300. The second dielectric layer 307 is disposed between the charge liner layer 305 and the conductive layer 308. In addition, the through-substrate via structure 30a further includes a barrier layer 306 disposed between the conductive layer 308 and the parasitic capacitance modulation layer 309.

In the through-substrate via structure 30 or 30a described in the present embodiment, the charged liner layer of the parasitic capacitance modulation layer is applied for reducing the depletion capacitance C_{dep}. In the disclosure, the charged liner layer having the fixed positive charges therein is arranged to push positive charges in the P⁺ substrate 300 around the opening 302 in an outward direction (schematically shown by arrows in FIG. 3B and FIG. 3B-1), so as to effectively reduce the depletion capacitance C_{dep} and further significantly reduce the overall parasitic capacitance C_{TSV}.

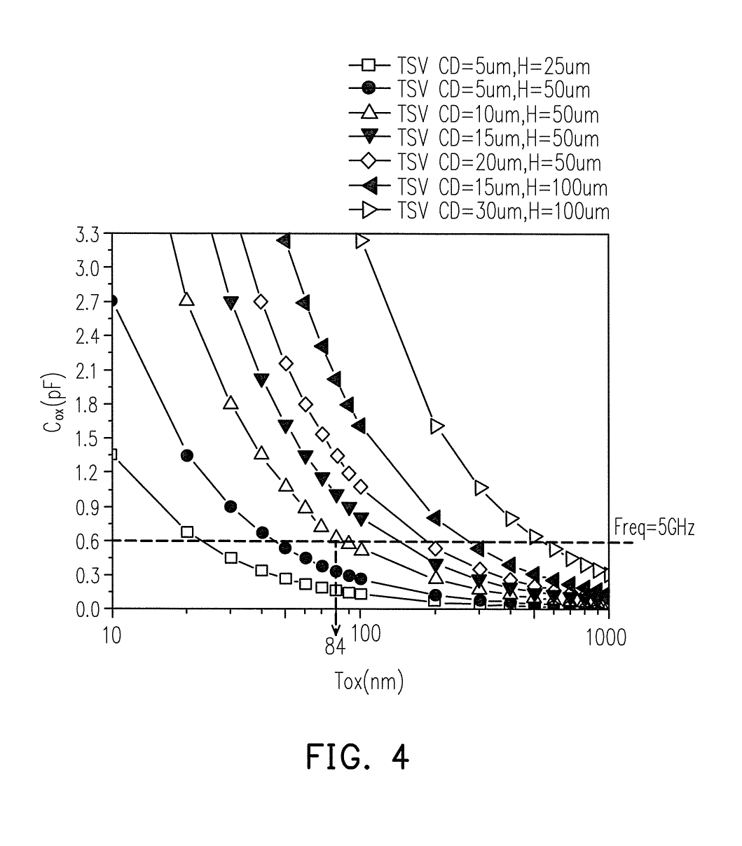

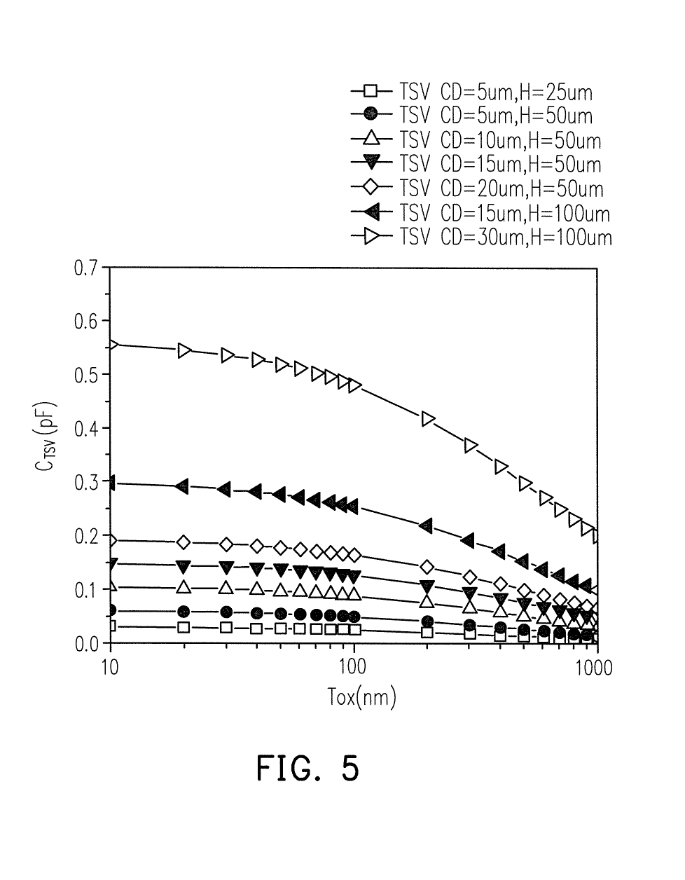

FIG. 4 shows curves representing relations of the parasitic capacitance C_{TSV} (i.e., the capacitance Cₒₓ of the liner layer) to the liner layer thickness Tₒₓ in a conventional through-silicon via (TSV) structure, wherein different curves denote cylindrical TSVs with different sizes. FIG. 5 shows curves representing relations of the parasitic capacitance C_{TSV} (i.e., the capacitance obtained by serially connecting the capacitance Cₒₓ of the liner layer and the depletion capacitance C_{dep}) to the liner layer thickness Tₒₓ in a TSV structure described in the disclosure, wherein different curves denote cylindrical TSVs with different diameters.

For instance, with reference to FIG. 4, given that the high frequency transmission is 5 GHz and the cylindrical TSVs have the critical dimension (CD) of 10 um and the height (H) of 50 um, the thickness of the liner layer is required to be at least 84 nm when the parasitic capacitance is expected to be reduced to 0.6 pF or less. However, due to design rules are scaled down, a thick liner layer may result in the sealing of the TSV, and thereby the TSV structure may no longer function.

With reference to FIG. 5, the TSV structure described in the present embodiment has the parasitic capacitance modulation layer, and the depletion capacitance C_{dep} generated by the TSV structure is 64.3 F (approximate to complete depletion). In the disclosure, the depletion capacitance C_{dep} and the capacitance Cₒₓ of the liner layer are serially connected. Since the depletion capacitance C_{dep} is rather small, the parasitic capacitance C_{TSV} of the TSV may be significantly reduced. Accordingly, even in the case of high frequency transmission, the parasitic capacitance of the TSV may be greatly reduced without thickening the liner layer.

To sum up, in the through-substrate via structure described in an embodiment of the disclosure, the parasitic capacitance modulation layer is placed around the through-substrate via to reduce the depletion capacitance and further reduce the parasitic capacitance of the through-substrate via. Therefore, during transmission of signals with high frequency, the parasitic capacitance around the through-substrate via is rather small and does not pose significant impact on the performance of transmission; thereby, the operation speed of devices may be increased.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

1. A semiconductor structure comprising:
a substrate having at least one opening;
a conductive layer filling up the opening; and
a parasitic capacitance modulation layer disposed between the conductive layer and the substrate, wherein the parasitic capacitance modulation layer comprises:
a charged liner layer;
a first dielectric layer disposed between the charged liner layer and the substrate; and
a second dielectric layer disposed between the charged liner layer and the conductive layer; and
a barrier layer, disposed between the conductive layer and the second dielectric layer,
wherein the semiconductor structure having the parasitic capacitance modulation layer reduces a parasitic capacitance between the conductive layer and the substrate more than a semiconductor structure without the parasitic capacitance modulation layer.

2-10. (canceled)

11. (canceled)

12. The semiconductor structure as recited in claim 1, wherein when the substrate is a p-type substrate, the charged liner layer has fixed positive charges therein.

13. The semiconductor structure as recited in claim 1, wherein a material of the charged liner layer comprises silicon oxide, silicon nitride, or silicon oxynitride.

14. (canceled)

15. The semiconductor structure as recited in claim 1, wherein the first dielectric layer and the second dielectric layer are both non-charged dielectric layers.

16. The semiconductor structure as recited in claim 15, wherein a material of each of the first dielectric layer and the second dielectric layer comprises silicon oxide, silicon nitride, or silicon oxynitride.

17. The semiconductor structure as recited in claim 15, wherein a material of the first dielectric layer is the same with or different from a material of the second dielectric layer.

18. (canceled)

19. The semiconductor structure as recited in claim 1, wherein a material of the conductive layer comprises copper, and a material of the barrier layer comprises titanium nitride, tantalum, or tantalum nitride.

20. The semiconductor structure as recited in claim 1, wherein a material of the substrate comprises silicon.

21. The semiconductor structure as recited in claim 1, wherein when the substrate is an n-type substrate, the charged liner layer has fixed negative charges therein.
